(19) United States
(12) Patent Application Publication
(10) Pub. No.: US 2025/0014812 A1
(43) Pub. Date: Jan. 9, 2025

(54) CHOKE MODULE

(71) Applicant: TDK Europe GmbH, Muenchen (DE)

(72) Inventors: Shinichiro Nishizawa, Muenchen (DE); Uzzal Binit Bala, Muenchen (DE)

(21) Appl. No.: 18/712,642

(22) PCT Filed: Oct. 27, 2022
(86) PCT No.: PCT/EP2022/080037

§ 371 Date: May 22, 2024

(30) Foreign Application Priority Data
Nov. 30, 2021 (DE) 102021131439.9

(51) Int. Cl. H01F 27/40; H01F 3/10; H01F 27/06

(52) U.S. Cl. CPC H01F 27/40; H01F 3/10; H01F 27/06; H01F 2003/106

(57) ABSTRACT

In an embodiment a choke module includes a choke with a magnetic core and at least one winding, a support including at least one integrated capacitor, and an input terminal and an output terminal, wherein the choke is located on the support, and wherein each capacitor integrated in the support is connected to the choke only by being connected to the output terminal.

### CROSS-REFERENCE TO RELATED APPLICATIONS

This patent application is a national phase filing under section 371 of PCT/EP2022/080037, filed Oct. 27, 2022, which claims the priority of German patent application 102021131439.9, filed Nov. 30, 2021, each of which is incorporated herein by reference in its entirety.

### TECHNICAL FIELD

The present invention is directed to a choke module, in particular an EMC-filter module for reducing electromagnetic interference noise. The choke module may comprise a common mode choke. Such a common mode choke comprises two or more windings around a magnetic core. The windings comprise metallic wires. The material of the wires, the core and the number of winding turns define electrical parameters like inductance, losses and EMC noise attenuation. Generally, increasing the number of turns in the windings leads to an improvement of noise attenuation characteristics, at least in low frequency ranges. However, noise attenuation levels in high frequency ranges from 10 MHz to 1000 MHz, for example, are diminished due to parasitic capacitance effects between the windings. These parasitic capacitance effects increase proportionally with the number of turns in the windings and with increasing the frequency.

### BACKGROUND

EMC-filters (EMC: electromagnetic compatibility) are widely used for reducing noise in electric and electronic products, power electronic products such as inverters and DC-DC converters. In EMC-Filters, a common mode choke is electrically connected with passive components to achieve an optimum and maximum filtering effects and attenuation of the EMC noise level. Said passive components may comprise an inductance, a capacitance, a resistance and combinations thereof.

Application areas are the automotive field, in particular autonomous driving systems with low voltage components and all forms of electric vehicles (xEV) with high voltage components, industrial products and consumer electronic products. EMC-filter chokes are usually interconnected in an EMC filter with one or more capacitors in order to improve the damping properties both at low and at high frequencies.

A capacitor can be integrated into a printed circuit board on which the choke is arranged to reduce the noise in the high frequency range of 10 MHz to 1000 MHz, in particular from 50 MHz to 300 MHz. However, a drawback of the integrated capacitor is that the integrated capacitor may provide a resonance which reduces the noise attenuation in a sub range of the high frequency range.

### SUMMARY

Embodiments provide an improved choke module. For example, embodiments provide a choke module, wherein the reduction in the noise attenuation due to the resonance provided by the integrated capacitor is damped and/or shifted to a frequency range outside of the high frequency range.

According to one embodiment, a choke module is provided which comprises a choke and a support. The choke comprises a magnetic core and at least one winding. The support comprises at least one integrated capacitor, wherein the choke is located on the support. The choke module comprises an input terminal and an output terminal. Each capacitor integrated in the support is connected to the choke only by being connected to the output terminal.

The input terminal of the choke module may penetrate each of the at least integrated capacitor, which may be a capacitor integrated into a main printed circuit board or a baseplate capacitor, and may have no connection with any of the at least one integrated capacitor. The integrated capacitor, which may be a capacitor integrated into a main printed circuit board or a baseplate capacitor, may not be connected to an input signal line connecting an input end of the choke to the input terminal.

The circuit layout, in which the integrated capacitor, which may be a capacitor integrated into a main printed circuit board or a baseplate capacitor, is not connected to the input signal line, may ensure that a signal applied to the input terminal first flows through the at least one winding of the choke before reaching the integrated capacitor. Accordingly, a rest impedance provided by the choke may be utilized to damp any noise in the signal applied to the input terminal before the signal reaches the integrated capacitor, which may be a capacitor integrated into a main printed circuit board or a baseplate capacitor. Thus, the noise in the signal cannot create resonance effects which would reduce the attenuation of the choke module, or at least the resonance effects are reduced by the circuit design.

The circuit layout utilizes the components of the choke module, i.e. the choke and the integrated capacitor, without requiring additional discrete elements to provide a good noise attenuation or at least with requiring a low number of additional discrete elements. Accordingly, no or a low number of additional discrete elements and thus no or little additional space is required for the circuit design.

The integrated capacitor, which may be a capacitor integrated into a main printed circuit board or a baseplate capacitor, in particular increases the attenuation of the choke module at high frequencies. By connecting the integrated capacitor only to an output signal line which connects the choke to the output terminal, the unwanted resonance effects being created by the integrated capacitor may be reduced or shifted to a lower frequency range, thereby improving the noise attenuation in the high frequency range.

The support comprising the at least one integrated capacitor may be a baseplate capacitor. The term “baseplate capacitor” shall refer to a baseplate on which the choke is arranged and which has a capacitive function. In particular, the layers of the baseplate may form a capacitor, the so-called baseplate capacitor. Alternatively, the support may be a main printed circuit board. The support may have lateral dimensions which are smaller, same or larger than the lateral dimensions of the choke.

The choke may be a common mode choke for reducing electromagnetic interference noise. The choke module may be designed to be arranged between a power source, for example a battery, and a load, for example a motor, in particular a motor of an electric vehicle. The input terminals are configured to be connected to the power source and the output terminals are configured to be connected to the load.

The support, which may be a baseplate capacitor or a main printed circuit board, may be an FR4-board, a flexible board or a low temperature co-fired ceramics board, which are based on glass reinforced epoxy laminate, synthetic materials and ceramics, respectively. The support, which may be a baseplate capacitor or a main printed circuit board, may be a multilayer board. The integrated capacitor may be formed by structured layers of the support, which may be a baseplate capacitor or a main printed circuit board. The term “integrated” shall be understood such that the capacitor is embedded in the support, which may be a baseplate capacitor or a main printed circuit board, or formed by layers of the support, which may be a baseplate capacitor or a main printed circuit board. A capacitor arranged on the surface of the support as a discrete element shall not be understood as an integrated capacitor.

The electrode layers of the capacitor, which may be a capacitor integrated into a main printed circuit board or a baseplate capacitor, may be formed by screen-printing on an insulating dielectric layer and/or etching a metallic layer, such as a copper layer, located on the insulating dielectric layer. The electrode layers may comprise copper or may consist of copper. The input terminals of the choke module may be configured to be connected to other elements, in particular to a voltage source configured to apply an input signal. The output terminals of the choke module may be configured to be applied to other elements, in particular to a load.

The choke and the integrated capacitor, which may be a capacitor integrated into a main printed circuit board or a baseplate capacitor, may be interconnected such that the signal applied at the input terminal of the choke module flows through the choke before flowing through any one of the at least one integrated capacitor. This design of the circuit formed by the choke and the integrated capacitor may utilize a rest impedance of the choke, in particular in a high frequency region, to damp any noise in a signal applied at the input terminal. Thus, the capacitor may get into contact with less noise. Accordingly, any resonance created by the capacitor may not have a strong effect on the attenuation of the choke module.

The integrated capacitor, which may be a capacitor integrated into a main printed circuit board or a baseplate capacitor, may be connected to ground. Accordingly, the integrated capacitor may be connected in series between the output signal line and ground. The integrated capacitor may be formed as a Y-capacitor.

The integrated capacitor, which may be a capacitor integrated into a main printed circuit board or a baseplate capacitor, may be formed by structured layers of the support, which may be the main printed circuit board or the baseplate forming the baseplate capacitor.

The magnetic core may comprise a first core part comprising a first material and a second core part comprising a second material, wherein the first material is different from the second material. The first core part may consist of the first material. The second core part may consist of the second material. By providing two different core parts comprising different materials, the impedance of the choke may be improved. In particular, one core part, for example the second core part, can be specially designed to provide a large impedance in the high frequency region, thereby damping noise in the high frequency region. The addition of a second core part with a different material may thus further reduce the amount of noise in the signal that reaches the integrated capacitor. Thereby, the resonance effects are further damped.

The first material may be manganese zinc. The second material may be nickel zinc. Nickel zinc provides the advantage of very high impedance for high frequencies.

The volume of the second core part may be smaller than the volume of the first core part. A second core part having a small volume is sufficient to achieve the desired high impedance in the high frequency region. Accordingly, there may not be a need to provide a large volume of the second material. Thus, the material usage and the costs for the second material may be kept low.

The first core part and the second core part each may be ring-shaped and differ in their diameter. For example, the second core part may be arranged outside the first core part. The second part may follow the first core part in a radial direction. Alternatively, the first core part may have a larger diameter than the second core part and in a radial direction the second core part may be arranged inside the first core part.

The support, which may be a baseplate capacitor or a main printed circuit board, may comprise at least one ground terminal configured to be connected to a grounded surface.

The support, which may be a baseplate capacitor or a main printed circuit board, may comprise an input end and an output end. The input terminals of the choke module may be arranged in close proximity to the input end of the support, which may be a baseplate capacitor or a main printed circuit board. The output terminal of the choke module may be arranged in close proximity to the output end of the support, which may be a baseplate capacitor or a main printed circuit board. All ground terminals of the support, which may be a baseplate capacitor or a main printed circuit board, may be arranged at the output end of the support. Accordingly, all ground terminals of the support, which may be a baseplate capacitor or a main printed circuit board, may be arranged close to the output terminal of the choke module. The choke module has a high impedance at its output terminal. The arrangement of all ground terminals close to the output terminal may ensure that noise coupling over the grounded surface is prevented.

The choke module may be configured as a common mode choke for reducing electromagnetic interference noise.

### BRIEF DESCRIPTION OF THE DRAWINGS

In the following, preferred embodiments of the choke module are described with reference to the figures.

FIG. 1 shows a choke module according to a first embodiment;

FIG. 2 shows a diagram of a filter circuit;

FIGS. 3 to 6 show a choke module according to a second embodiment;

FIG. 7 shows simulation results comparing an attenuation of the choke module as shown in FIGS. 3 to 6 to two comparative examples;

FIG. 8 shows a diagram of a filter circuit of a x-filter;

FIGS. 9 to 11 show a comparative embodiment;

FIG. 12 shows a choke module according to a third embodiment;

FIG. 13 shows a choke module according to a fourth embodiment;

FIG. 14 shows a choke module according to a fifth embodiment;

FIG. 15 shows an attenuation of a choke module as shown in FIG. 14 compared to two reference examples; and

FIG. 16 shows a choke module according to a reference example.

### DETAILED DESCRIPTION OF ILLUSTRATIVE EMBODIMENTS

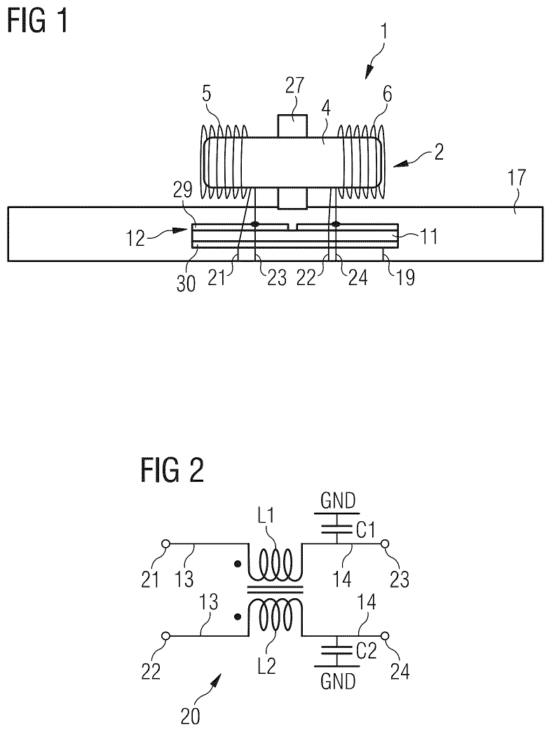

FIG. 1 shows the choke module 1 comprising a choke 2 located on a support in a cross-sectional view. The support is a main printed circuit board 17. The choke 2 comprises a magnetic core 4 and two windings 5, 6 on the magnetic core 4.

The choke 2 is a common mode choke for reducing electromagnetic interference noise, for example. In particular, the choke 2 serves as a filter for providing electromagnetic compatibility (EMC).

The choke module comprises input terminals 21, 22 and output terminals 23, 24. The input terminals 21, 22 may be connected to a voltage source, e.g., to a battery. An input signal may be provided to the choke 2 via the input terminals. The output terminals 23, 24 may be connected to a load, e.g., to a motor. The choke 2 provides a filtered output signal which is provided at the output terminals 23, 24.

A capacitor 12 is integrated in the main printed circuit board 17. The output terminals 23, 24 of the choke module are connected to the integrated capacitor 12. In particular, the output terminals 23, 24 are connected to electrodes in a first electrode layer 29 of the integrated capacitor 12. The input terminals 21, 22 penetrate the integrated capacitor 12 without being connected to the integrated capacitor 12.

The choke module 1 further comprises a pin-shaped ground terminal 19 that may be configured to be connected to ground. The pin-shaped ground terminal 19 is connected to a second electrode layer 30 of the integrated capacitor 12.

The main printed circuit board 17 supports the choke 2 mechanically.

A fixation element 27 may fix the choke 2 on the main printed circuit board 17. The fixation element 27 may be attached to the main printed circuit board 17 by snap-fitting, for example. The fixation element 27 may also be an integral part of the main printed circuit board 17. The choke 2 may be fixed to the fixation element 27 by snap-fitting, for example.

The main printed circuit board 17 has not only a support functionality, but also a capacitor functionality due to the integrated capacitor 12. The integrated capacitor 12 is integrated into the material of the main printed circuit board 17. The main printed circuit board 17 comprises a multilayer structure and the integrated capacitor 12 is formed by layers of the multilayer structure.

The integrated capacitor 12 comprises the dielectric layer 11 sandwiched between the first electrode layer 29 and the second electrode layer 30. The dielectric layer 11 and the electrode layers 29, 30 form two capacitances C1, C2. The first electrode layer 29 may comprise several separate electrodes and the second electrode layer 30 may comprise a single second electrode. A dielectric cover layer may be arranged on the first electrode layer 29 and/or on the second electrode layer 30.

The dielectric layer 11 may comprise a plastic material or may consist of a plastic material. The dielectric layer 11 may comprise or consist of an epoxy resin. In particular, the dielectric layer 11 may comprise or consist of an FR4-material.

The electrodes formed by the first electrode layer 29 and by the second electrode layer 30 may be conductive plates fixed to the dielectric layer 11. The electrodes may be also applied to the dielectric layer 11 by screen printing and/or galvanic processes. The electrodes may comprise or consist of copper.

The integrated capacitor 12 may comprise multiple dielectric layers 11, multiple first electrode layers 29 and multiple second electrode layers 30 which are stacked on each other such that each dielectric layer 11 is sandwiched between a first electrode layer 29 and a second electrode layer 30. Alternatively, integrated capacitor 12 comprises one dielectric layer 11, one first electrode layer 29 and one second electrode layer 30 stacked on each other.

In the choke module 1 shown in FIG. 1, the choke 2 is horizontally mounted, i.e., a symmetry axis of the round magnetic core 4 is perpendicular to an upper surface of the main printed circuit board 17. In other embodiments, the choke 2 may be vertically mounted, i.e., the symmetry axis of the round magnetic core 4 may be parallel to the upper surface of the main printed circuit board 17.

The choke module comprises the above-described pin-shaped ground terminal 19. The pin-shaped ground terminal 19 is connected to the second electrode layer 30. The choke module 1 is configured to be arranged in a housing. The pin-shaped ground terminal 19 can be connected to a ground surface of the housing, for example by a pin-through-hole technology.

FIG. 2 shows a diagram of a filter circuit 20. In particular, the choke module 1 of FIG. 1 may be connected according to the filter circuit 20.

In the circuit diagram, the choke 2 forms two inductance L1, L2 provided by the windings 5, 6. The inductances L1, L2 are coupled via the magnetic core 4.

The first input terminals 21 of the choke module is connected by an input signal line 13 to the inductance L1. The second input terminals 22 of the choke module is connected by another input signal line 13 to the inductance L2. The inductance L1 is connected by an output signal line 14 to a first output terminal 23 of the choke module. The inductance L2 is connected by another output signal line 14 to a second output terminal 23 of the choke module.

Two capacitances C1, C2 are formed by the integrated capacitor 12. The capacitances C1, C2 are connected between the output signal lines 14 and ground. Such capacitance connected between the output signal line 14 and ground are so-called Y-capacitors. Accordingly, the capacitances C1, C2 are connected to the output terminals 23, 24 of the choke module 1. No capacitance is connected to the input terminal 21, 22 of the choke module 1. Accordingly, no capacitance is connected to the input signal lines 13 connecting the input terminal 21, 22 of the choke module 1 and the choke 2.

The layout of the filter circuit 20 ensures that any signal applied to the input terminal 21, 22 first flows through the inductances L1, L2 and reaches the capacitance C1, C2 formed by the integrated capacitor 12 after flowing through the inductances. This layout ensures that noise in the signal applied to the input terminal 21, 22 is filtered by the inductances L1, L2 before reaching the capacitances C1, C2. In particular, low frequency noise is filtered by the inductances L1, L2.

The impedance of the two inductances L1, L2 can be utilized to reduce the noise, e.g., input signal or created resonance. Thus, resonance effects created by the capacitances C1, C2, in particular in the FM radio frequency range, can be attenuated by the impedance of the two inductances L1, L2. As the impedance of the two inductances L1, L2 of the choke 2 is utilized to attenuate the noise in the signal, no additional discrete component or at least a lower number of additional discrete components is required in the choke module 1. Instead, the existing elements of the choke module 1 are used in the present design of the filter circuit 20 to attenuate noise in the signal.

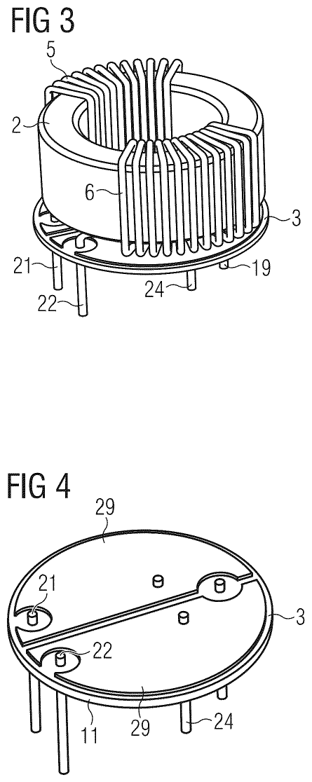

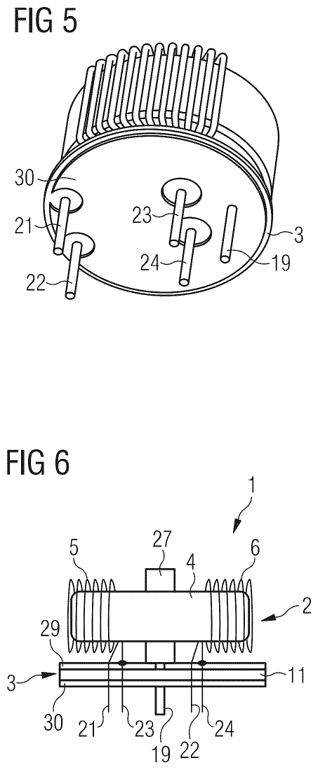

FIGS. 3 to 6 show a choke module 1 according to a second embodiment. FIG. 3 shows a perspective top view of the choke module 1 according to the second embodiment. FIG. 4 shows a perspective top view of a baseplate capacitor of the choke module 1 according to the second embodiment. FIG. 5 shows a perspective bottom view of the choke module 1 according to the second embodiment. FIG. 6 schematically shows a cross-sectional view.

The choke module 1 according to the second embodiment differs from the choke module shown in FIG. 1 in particular in the size of the support.

In the second embodiment, the support is a baseplate capacitor 3. The baseplate capacitor 3 is a plate on which the choke 2 is arranged, which supports the choke 2 mechanically and which provides a capacitive function because its layers are structured to form at least one capacitance. The baseplate capacitor 3 is a plate capacitor having lateral dimensions that are only slightly larger than the lateral dimensions of the choke 2. For example, the lateral dimensions of the baseplate capacitor 3 may not be larger by more than 25% compared to the lateral dimensions of the choke 2, preferably not larger by more than 10%. The choke 2 and the baseplate capacitor 3 both have a circular shape wherein the lateral dimensions refer to a diameter of the circular shape.

The output terminals 23, 24 of the choke module 1 may be connected to the baseplate capacitor 3 by pin-through-hole mounting, for example. The input terminals 21, 22 penetrate through the baseplate capacitor 3 without being connected to the baseplate capacitor.

The baseplate capacitor 3 may be configured to be placed on a main board. On the main board other passive and/or active components and/or modules may be located. The terminals 21, 22, 23, 24 of the choke module 1 may be configured to be soldered to the main board. As an example, the terminals 21, 22, 23, 24 may be attached by pin-through-hole mounting.

The baseplate capacitor 3 of the second embodiment is a capacitor formed by layers of the support on which the choke 2 is arranged. The baseplate capacitor 3 comprises first electrode layers 29, a dielectric layer 11 and second electrode layers 30. The baseplate capacitor 3 and the choke 2 are connected to each other to form the filter circuit 20 as shown in FIG. 2. The baseplate capacitor 3 forms the two capacitances C1, C2. As discussed above with respect to the first embodiment, the impedance of the choke 2 is utilized to damp any noise in an input signal applied at the input terminals 21, 22 before this signal reaches the baseplate capacitor 3. Therefore, any unwanted resonance created by the baseplate capacitor 3 can be damped as less noise is applied to the baseplate capacitor 3.

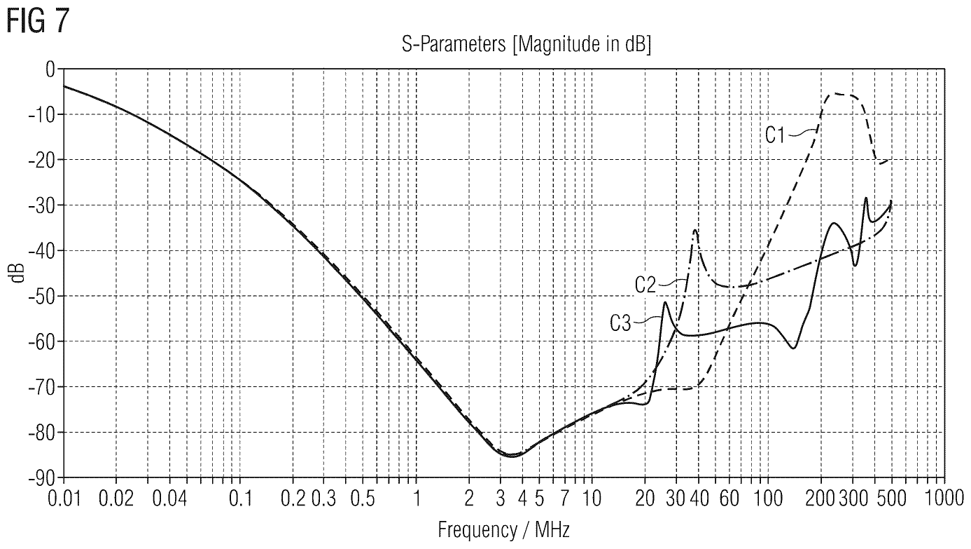

FIG. 7 shows simulation results comparing the attenuation of the choke module 1 as shown in FIGS. 3 to 6 to two comparative examples which will be described in the next paragraph. In FIG. 7, the frequency of an input signal applied to the input terminals 21, 22 is plotted on the horizontal axis. On the horizontal axis, the frequency is plotted in MHz in a logarithmic scale. On the vertical axis, the attenuation of a corresponding output signal provided by the choke module 1 is plotted. The attenuation is plotted in dB.

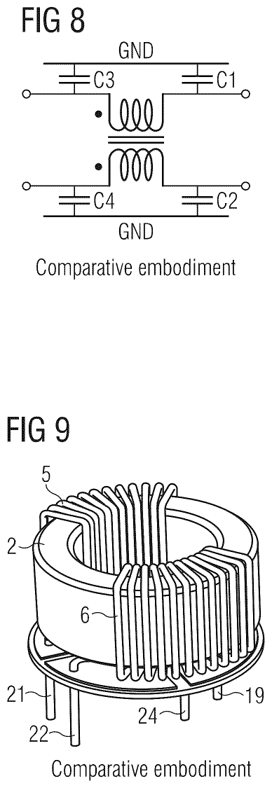

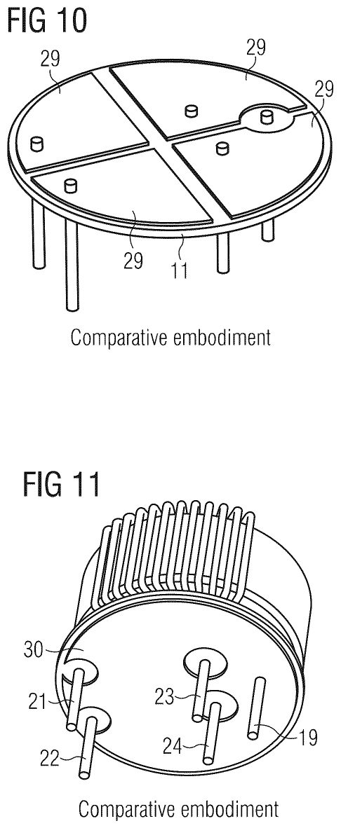

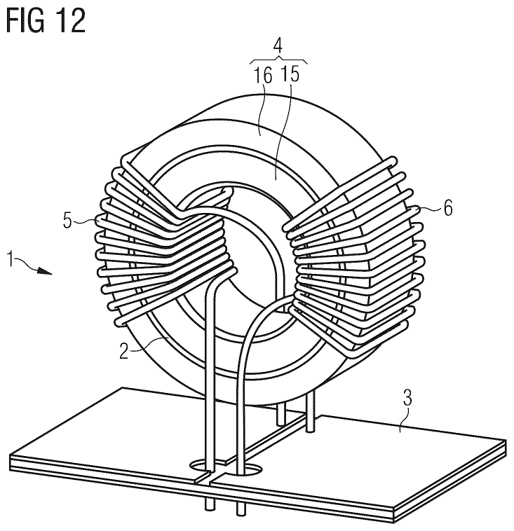

The curve C1 shows the attenuation of a first comparative example. In the first comparative example, the choke is arranged on a support which does not comprise an integrated capacitor. The curve C2 shows the attenuation provided by a second comparative example. The choke module of the second comparative example comprises a choke arranged on a support which forms a baseplate capacitor similar to the embodiment shown in FIGS. 3 to 6. In the second comparative example, the baseplate capacitor and the choke are connected to form a x-filter. Accordingly, the electrode layers and the dielectric layers of the second comparative embodiment are structured to form two additional capacitances C3, C4 which are connected between the input signal lines and the ground, as shown in FIG. 8. Details on the structuring of the first electrode layer of the second comparative embodiment are shown in FIGS. 9 to 11.

Curve C3 shows the attenuation of the choke module 1 shown in FIGS. 3 to 6 wherein the choke 2 and the baseplate capacitor 3 are connected to each other to form the filter circuit 20 shown in FIG. 2.

Curves C2 and C3 show a significantly improved attenuation in the high frequency range 50 to 300 MHz compared to curve C1. The addition of the baseplate capacitor 3 connected to the choke 2 reduces the noise in this frequency range. Curve C3 shows an improved attenuation compared to curve C2. By connecting the baseplate capacitor 3 and the choke 2 according to the filter circuit 20 of FIG. 2, the impedance of the choke 2 can be utilized to damp noise in the input signal, thereby improving the attenuation of the choke module 1 as less noise is applied to the capacitances.

Moreover, a comparison of curves C2 and C3 shows that a resonance peak which is created by a resonance of the baseplate capacitor 3 in combination with further passive components is shifted to lower frequencies, further away from the critical frequency range. This also improves the performance of the choke module 1.

FIG. 12 shows the choke module 1 according to a third embodiment. In the choke module according to the third embodiment, the magnetic core 4 of the choke 2 comprises a first core part 15 comprising a first material and a second core part 16 comprising a second material. Each of the core parts 15, 16 is ring-shaped wherein the second core part 16 has a larger diameter than the first core part 15.

The first material of the first core part 15 is manganese zinc (MgZn). The second material of the second core part 16 is nickel zinc (NiZn). Manganese zinc is a ferrite material which is commonly used to form a magnetic core of a choke. Compared to nickel zinc, manganese zinc has a comparatively low impedance at high frequencies. Nickel zinc provides an improved impedance at high frequencies which allows to damp noise at high frequencies. By combining two separate core parts 15, 16 having different materials, the noise can be attenuated by the magnetic core 4 in low and high frequencies. Compared to a magnetic core 4 consisting only of one core part which consists of one material, the magnetic core 4 of the third embodiment provides an improved impedance and therefore an improved attenuation.

The choke module 1 of the third embodiment also comprises a baseplate capacitor 3 wherein the choke 2 is arranged on the baseplate capacitor 3. In the embodiment shown in FIG. 12, the base plate capacitor is rectangular.

FIG. 12 shows a choke 2 which is vertically mounted on the baseplate capacitor 3. The choke 2 comprising a magnetic core 4 with two separate core parts 15, 16 may also be mounted horizontally on the baseplate capacitor 3 or on the main printed circuit board 17 in an alternative embodiment.

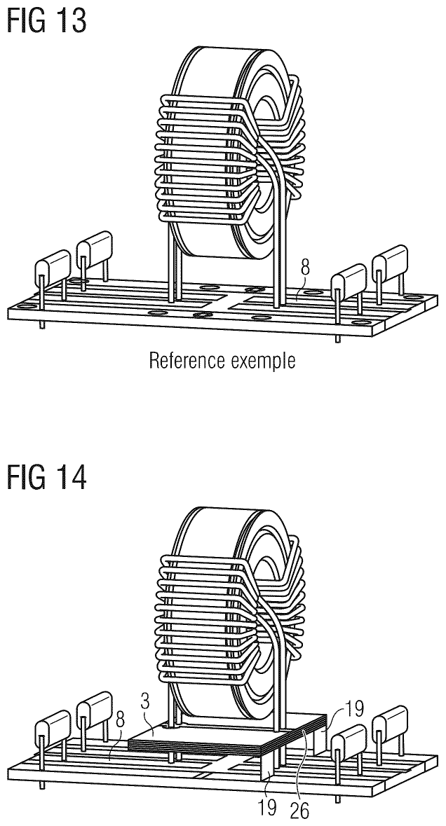

FIG. 13 shows a choke module according to a reference example wherein a choke 2 comprising a magnetic core 4 is arranged on a main board 8 without an integrated capacitor. Discrete components are arranged on the main printed circuit board 17.

FIG. 14 shows a choke module 1 according to a fourth embodiment. The choke module 1 comprises a choke 2 mounted on a baseplate capacitor 3. The baseplate capacitor 3 is mounted on a main board 8.

The baseplate capacitor 3 comprises an input end 25 and an output end 26 which is opposite to the input end 25. The term “input end” shall refer to the end of the baseplate capacitor 3 which is close to the input terminals 21, 22 of the choke module. The term “output end” shall refer to the end of the support which is close to the output terminals 23, 24 of the choke module.

The baseplate capacitor 3 is connected to the main board 8 by the plate-shaped ground terminals 19. In particular, two plate-shaped ground terminals 19 are connected to a grounded surface of the main board 8. As can be seen in FIG. 14, both plate-shaped ground terminals 19 are arranged at the output end 26 of the baseplate capacitor 3. Accordingly, the output terminals 23, 24 are arranged close to the plate-shaped ground terminals 19. This arrangement of the plate-shaped ground terminals 19 ensures that noise coupling over the ground surface of the main board 8 is prevented. Close to the output terminals 23, 24, the choke module 1 has a high impedance such that noise coupling over the ground surface can be avoided. The baseplate capacitor 3 does not comprise ground terminals 19 which are arranged at the input end 25.

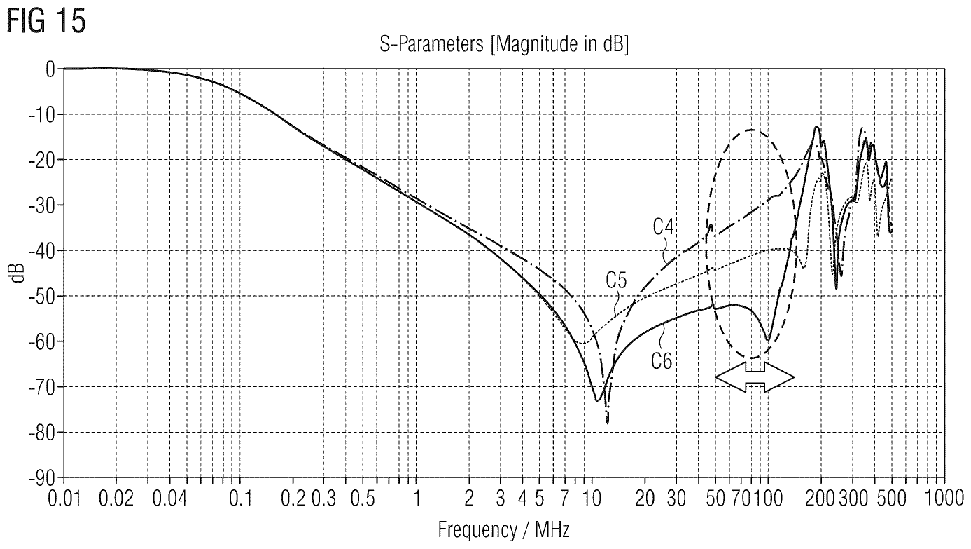

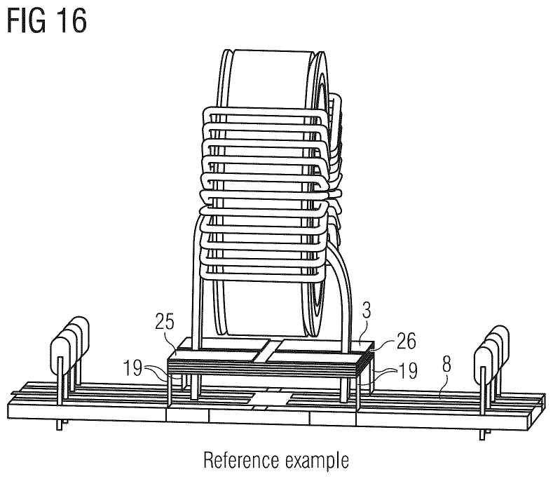

FIG. 15 shows the attenuation of a choke module 1 as shown in FIG. 14 compared to two reference examples which will be described in the next paragraph. On the horizontal axis, the frequency in MHz is plotted in a logarithmic scale and on the vertical axis, the attenuation in dB is plotted.

Curve C4 shows the attenuation of the first reference example, which is a choke module that does not comprise a support with an integrated capacitor as shown in FIG. 13. Curve C5 shows the attenuation provided by a second reference example, which is shown in FIG. 16. The choke module of the second reference example comprises a baseplate capacitor 3 wherein, compared to the fourth embodiment shown in FIG. 14, additional plate-shaped ground terminals 19 are arranged close to the input end 25 of the choke module. In the second reference example, noise can be coupled from the plate-shaped ground terminals 19 close to the input terminals and to the plate-shaped ground terminals 19 close to the output terminals over the ground surface of the main board 8. Curve C6 shows the noise attenuation provided by the embodiment shown in FIG. 14.

FIG. 15 shows that each of curves C5 and C6 provides an improved attenuation compared to curve C4. This improvement in the attenuation is provided by the addition of the baseplate capacitor 3. When comparing curves C5 and C6, curve C6 provides an attenuation which is improved by roughly 10 dB compared to curve C5. The improvement in the attenuation of curve C6 is due to the arrangement of all plate-shaped ground terminals 19 close to the output end 26 which avoids noise coupling over the ground surface of the main board 8.

The arrangement of all plate-shaped ground terminals 19 close to the output end 26 can be applied to all previously shown embodiments.

1.-15. (canceled)

16. A choke module comprising:
a choke with a magnetic core and at least one winding;
a support comprising at least one integrated capacitor; and
an input terminal and an output terminal,
wherein the choke is located on the support, and
wherein each capacitor integrated in the support is connected to the choke only by being connected to the output terminal.

17. The choke module according to claim 16, wherein the input terminal of the choke module penetrates each of the at least one integrated capacitor and has no connection with any of the at least one integrated capacitor.

18. The choke module according to claim 16, wherein the support comprises the at least one integrated capacitor is a baseplate capacitor.

19. The choke module according to claim 18,
wherein the baseplate capacitor comprises:
at least one plate-shaped ground terminal configured to be connected to a grounded surface, and
an input end and an output end,
wherein the input terminal of the choke module is arranged in close proximity to the input end of the baseplate capacitor,
wherein the output terminal of the choke module is arranged in close proximity to the output end of the baseplate capacitor, and
wherein all plate-shaped ground terminals of the baseplate capacitor are arranged at the output end of the baseplate capacitor.

20. The choke module according to claim 19, wherein ground planes are arranged such that a noise coupling over the grounded surface is prevented.

21. The choke module according to claim 16, wherein the support is a main printed circuit board into which the at least one capacitor is integrated and on which at least one discrete component is arranged.

22. The choke module according to claim 16, wherein the choke and the at least one integrated capacitor are interconnected such that a signal applied at the input terminal of the choke module is processed at the choke before it is processed at any one of the at least one integrated capacitor.

23. The choke module according to claim 16, wherein each of the at least one integrated capacitor is connected to ground.

24. The choke module according to claim 16, wherein the integrated capacitor is formed by layers of the support.

25. The choke module according to claim 16, wherein the magnetic core comprises a first core part comprising a first material and a second core part comprising a second material, and wherein the first material is different from the second material.

26. The choke module according to claim 25, wherein the first material is MgZn.

27. The choke module according to claim 25, wherein the second material is NiZn.

28. The choke module according to claim 25, wherein a volume of the second core part is smaller than a volume of the first core part.

29. The choke module according to claim 25, wherein the first core part and the second core part are each ring shaped and differ in their diameter.

30. The choke module according to claim 25, wherein the choke module is a common mode choke configured to reduce electromagnetic interference noise.
